(19) United States
(12) Patent Application Publication
(10) Pub. No.: US 2002/0153523 A1
(43) Pub. Date: Oct. 24, 2002

(54) Organic light emitting diodes on plastic substrates

(76) Inventors: Mark T. Bernius, Midland, MI (US); Martin C. Cornell, Lake Jackson, TX (US); Ing-Feng Hu, Midland, MI (US); Scott Kisting, Midland, MI (US)

Correspondence Address: THE DOW CHEMICAL COMPANY, INTELLECTUAL PROPERTY SECTION, P. O. BOX 1967, MIDLAND, MI, 48641-1967, US

(21) Appl. No.: 10/068,356

(22) Filed: Feb. 4, 2002

Related U.S. Application Data
(60) Provisional application No. 60/266,490, filed on Feb. 5, 2001.

(51) Int. Cl. H01L 35/24; H01L 51/00

(52) U.S. Cl. 257/40

(57) ABSTRACT

The invention is an optoelectronic device comprising a transparent polymeric substrate bearing on one surface thereof a transparent polymerized organosilicon protective layer, a first electrode over the polymerized protective layer, an optoelectrically active film comprising an electroactive material, said film having a first side, which is in contact with the transparent electrode and a second side in contact with a second electrode, wherein said first electrode is characterized in that it allows light to pass to or from the optoelectrically active film. Preferably, the device further comprises additional protective packaging over the second electrode.

### CROSS-REFERENCE TO RELATED APPLICATION

This Application claims the benefit of U.S. Provisional Application No. 60/266,490, filed Feb. 5, 2001.

### FIELD OF THE INVENTION

This invention relates to plastic substrates with excellent barrier properties for use in organic optoelectronic devices, such as light emitting diodes, thin film transistors, photodiodes, photovoltaic cells, and photodetectors.

### BACKGROUND OF THE INVENTION

Optoelectronic devices, such as photocells (e.g., photodetectors, photodiodes, photovoltaics) and electroluminescent (EL) elements (e.g., light emitting diodes—also referred to as LEDs) may be formed by sandwiching optically and electrically active materials between electrodes. When an EL device is subjected to an applied voltage, holes injected from the anode and electrons injected from the cathode will combine in the optoelectroactive material to form singlet excitons, which can undergo radiative decay, thereby liberating light. Conversely, in photocells, light that is incident upon the optoelectroactive material is converted into electric current.

Organic materials are becoming very attractive as optically and electrically active materials. Specifically, small organic molecules that have been taught to have electroluminescent properties include those taught by Tang and VanSlyke in U.S. Pat. No. 4,885,221 and by Tang in Information Display, pp. 16-19, October 1996. Polymeric, organic electroluminescent materials (e.g., polythiophenes, polyphenylene vinylenes, and polyfluorenes) are also useful. Polymers, which are solution processible, are most desirable for the ease of manufacture as these can easily be coated out of solution by various known coating methods. Fluorene based polymers are especially preferred (see, e.g., U.S. Pat. Nos. 5,708,130 and 5,728,801; WO97/33193, WO 00/06665 and WO 00/46321). Light emitting devices made with these organic electroluminescent materials are referred to as organic light emitting devices or OLEDs. Devices made with polymeric light emitting devices are referred to as polymeric light emitting devices (PLED).

Since transmission of light is fundamental to the performance of these optoelectronic devices, at least one of the electrodes much be structured to enable transmission of the light into or out of the device (to or from the optically and electrically active material). Typically, this is achieved by using a transparent conductive material—most notably indium tin oxide (ITO) on a transparent substrate. While glass is currently a common substrate used, there is a great deal of interest in using plastics, which may be less expensive and may be more resistant to breakage from rough handling that may occur in portable devices, such as cell phones. Use of plastics may also enable a wider variety of shaped and flexible displays. However, since OLEDs, and especially PLEDs, are frequently and conveniently fabricated by coating the organic or polymeric materials from a dispersion or solution in an organic solvent, it is necessary that the substrates be resistant to or able to withstand exposure to the solvents.

Moreover, protection of the active materials from environmental conditions has been found to be necessary to ensure good performance. In particular, materials sometimes used in the electrodes (e.g., calcium, magnesium, etc.) are known to be extremely sensitive to oxygen and moisture in ambient air. The electroactive organic films also need to be protected from moisture as charge injection (which takes place via radical species) can easily be impeded by the presence of oxygen and/or water. Thus, various protective packaging schemes have been proposed (see, e.g., WO 00/69002). WO 00/36665 also disclosed the concept of using barrier stacks comprising a polymer layer and a barrier layer on either side of an electroluminescent to protect OLEDs. The polymer layer is taught to be an acrylate-containing polymer, while the barrier layer is stated to be any barrier material, such as metal oxides, metal nitrides, metal carbides, metal oxynitrides and combinations thereof. WO 00/36665 then further teaches that these structures may be used in combination with substrate, which may be glass, metal, paper, fabric, etc., but is preferably a flexible polymeric material, such as polyethylene terephthalate (PET), or polyethlene naphthalate (PES) polyimides. Unfortunately, the approach described by WO 00/36665 requires numerous deposition steps to form the various layers required to be present to provide the barrier protection.

Thus, an OLED on a flexible, barrier protected substrate, which is easy to manufacture and requires few component layers, is still desired.

### BRIEF DESCRIPTION OF THE DRAWINGS

FIG. 1 is a cross-section of a representative embodiment of the device of the present invention.

### SUMMARY OF THE INVENTION

Applicants' invention is an optoelectronic device comprising

(a) a transparent polymeric substrate bearing on at least one surface thereof a transparent polymerized organosilicon protective layer,

(b) a first electrode over the polymerized protective layer,

(c) an optoelectrically active film comprising an electroactive material, said film having a first side, which is in contact with the transparent electrode, and a second side in contact with a second electrode, wherein said first electrode is characterized in that it allows light to pass to or from the optoelectrically active film. Preferably, the device further comprises additional protective packaging over the second electrode.

By “opto-electrically active film” is meant a single layer or multi-layer structure which is capable of transporting charge and which emits light when charge is transported through the film and/or generates current when light is incident upon the film. The film is preferably made predominantly, or more preferably, entirely, from organic materials.

“Electroactive material” and “optoelectronic material” are used synonymously herein as describing the organic material possessing electronically semiconductive characteristics, which is capable of converting electrical charge to light, or vice versa, or being utilized as a semiconducting switch as in a field-effect transistor as it is understood by practitioners in the art.

### DETAILED DESCRIPTION OF THE INVENTION

The optoelectronic device includes photodiodes, thin film transistors, photodetectors, and photovoltaics, but is preferably an electroluminescent device.

The transparent polymeric substrate may be any optically clear polymeric material. Examples of suitable thermoplastic materials include polyethylene, polypropylene, polystyrene, polyvinylacetate, polyvinylalcohol, polyvinylacetal, polymethacrylate ester, polyacrylic acids, polyether, polyester, polycarbonate, cellulous resin, polyacrylonitrile, polyamide, polyimide, polyvinylchloride, fluorine containing resins, and polysulfone. Examples of thermosets are epoxy, diallyl carbonate, and urea melamine.

The thickness of the substrate is application dependent, but is preferably not less than about 0.1 mm, more preferably not less than about 0.3 mm, and most preferably not less than about 0.5 mm, and preferably not more than about 10 mm, more preferably not more than about 5 mm, and most preferably not more than about 2 mm. Optionally, the substrate may include an external protective coating to protect against scratching of the surface and similar properties on the opposite side of the substrate from the surface bearing the polymerized organosilicon protective layer. The abrasion resistant coating may be any such known coating. The external protective coating may be the same as the polymerized organosilicon protective layer.

The polymerized organosilicon protective layer is preferably formed by plasma enhanced chemical vapor deposition, which initiates polymerization of an organosilicon compound in the presence of excess oxygen, as discussed in U.S. Pat. Nos. 5,718,967 and 5,298,587. Starting materials may include silane, siloxane, or a silazane. Examples of silanes include dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane, dimethoxymethylphenylsilane, phenyltrimethoxysilane, 3-glycidyloxypropyltrimethoxysilane, 3-methacryloxypropyltrimethoxysilane, diethoxymethylphenylsilane, tris(2-methoxyethoxy)vinylsilane, phenyltriethoxysilane, tetraethylorthosilane and dimethoxydiphenylsilane. Examples of siloxanes include tetramethyldisiloxane (TMDSO) and hexamethyldisiloxane. Examples of silazanes include hexamethylsilazane and tetramethylsilazane. The polymerized organosilicon protective layer preferably has the formula: SiO_{1.0-2.4}C_{0.1-4.5}H_{0.0-8.0}, more preferably SiO_{1.0-2.4}C_{0.2-2.4}H_{0.0-4.0}, and most preferably SiO_{1.8-2.4} C_{0.3-1.0} and H_{0.7-4.0}.

Preferably, the organosilicon protective layer includes an adhesion promoter layer adjacent to the substrate and between the substrate and the primary protective layer. The adhesion promoter layer may be any known suitable adhesion promoter but preferably is a first plasma polymerized organosilicon compound deposited on the surface of the substrate at a power level sufficient to create an interfacial chemical reaction for adhesion and in the substantial absence of oxygen. The protective coating layer is then a second plasma polymerized organosilicon compound (the primary protective layer) deposited on the surface of the adhesion layer at a power density from about 10⁶ J/kg to about 10⁸ J/kg, and in the presence of a higher level of oxygen than in the step of applying the adhesion promoter.

Thus, according to a preferred embodiment, the surface of the substrate is coated first with an adhesion promoter layer, which is formed from the plasma polymerization of an organosilicon compound deposited on the surface of the substrate. The plasma polymerization of the organosilicon compound to produce the adhesion promoter layer is carried out at a sufficient power level to create an interfacial chemical reaction for adhesion, preferably, at a power level from about 5×10⁷ J/kg to about 5×10⁹ J/kg. The adhesion promoter layer is prepared in the absence or substantial absence of a carrier gas, such as oxygen. The term “substantial absence of oxygen” is used herein to mean that the amount of oxygen present in the plasma polymerization process is insufficient to oxidize all the silicon and carbon in the organosilicon compound. Similarly, the term “stoichiometric excess of oxygen” is used herein to mean that the total moles of oxygen present is greater than the total moles of the silicon and carbon in the organosilicon compound.

The thickness of the adhesion promoter layer is application dependent and is preferably not less than about 50 Å, more preferably not less than about 500 Å, and most preferably not less than about 1000 Å, and preferably not more than about 10,000 Å, more preferably not more than about 5000 Å, and most preferably not more than about 2000 Å.

The adhesion promoter layer is then coated with a protective coating layer, which is a plasma polymerized organosilicon compound deposited on the surface of the adhesion promoter layer at a power density from about 10⁶ J/kg to about 10⁸ J/kg, and in the presence of a higher level of oxygen than used to form the adhesion promoter layer. Preferably, the protective coating layer is formed in the presence of a stoichiometric excess of oxygen.

The thickness of the protective coating for the substrate depends primarily on the properties of the coating, as well as the substrate, but in general, is sufficiently thick to impart solvent resistance to the substrate. Preferably, the coating thickness is not less than about 0.1 micron, more preferably not less than about 0.4 micron, and most preferably not less than about 0.8 micron, and not greater than about 10 microns, more preferably not greater than about 5 microns, and most preferably not greater than about 2 microns.

The protective layer structure, preferably, further comprises an SiOₓ layer, which is a plasma polymerized organosilicon compound, deposited on the surface of the layer of the protective coating layer, in the presence of a stoichiometric excess of oxygen, and at a power density of at least about twice, more preferably at least about 4 times, and most preferably at least about 6 times the power density used to form the protective coating layer. This layer is conveniently referred to as an SiOₓ layer. However, the SiOₓ layer may also contain hydrogen and carbon atoms. The thickness of the SiOₓ layer is generally less than the thickness of the protective coating layer, and is preferably not less than about 0.01 micron, more preferably not less than about 0.02 micron, and most preferably not less than about 0.05 micron, and preferably not more than about 5 microns, more preferably not more than about 2 microns, and most preferably not more than about 1 micron.

It may be desirable to coat the adhesion promoter layer with alternating layers of the protective coating layer and the SiOₓ layer. The ratio of the thicknesses of the protective coating layers and the SiOₓ layers are preferably not less than about 1:1, more preferably not less than about 2:1, and preferably not greater than about 10:1, more preferably not greater than about 5:1.

The laminate is optically clear and comprises a substrate having a stress optic coefficient (SOC) in the range of from about −2000 to about +2500 Brewsters and a T_{g}, as determined by differential scanning calorimetry, preferably in the range of from about 160° C. to about 270° C. Preferably, the SOC of the substrate is not less than about −1000, more preferably not less than about −500, and most preferably not less than about −100, and not greater than about 1000, more preferably not greater than about 500, and most preferably not greater than about 100 Brewsters. The T_{g} of the substrate is preferably not less than about 180° C., more preferably not less than about 190° C., and most preferably not less than about 200° C., to not greater than about 250° C., more preferably not greater than about 240° C., and most preferably not greater than about 230° C. The term “optically clear” is used herein to mean that the substrate has a measured total light transmission value according to ASTM D-1003 of at least about 80 percent, preferably at least about 85 percent.

The first electrode is preferably a transparent conductive material such as ITO, but may alternatively be a line, series of lines or grid of an opaque material, in which case light incident upon or emitted from the optoelectrically active layer is able to pass around the sides of the electrode, as discussed in U.S. Provisional Application Serial No. 60/259,490, filed Jan. 3, 2001. When the electrode is made of ITO, the ITO can be vapor deposited onto the protective layer according to normal procedures for depositing ITO onto substrates.

The optoelectrically active material is then applied over the electrode according to known procedures. These procedures include spin coating and other solvent casting methods. While the devices of this invention include those having optoelectrically active layers based on small organic molecules, see, e.g., Tang and VanSlyke in U.S. Pat. No. 4,885,221 and Tang in Information Display, pp. 16-19, October 1996, materials such as phenylenevinylene based polymers, thiophene based polymers, and fluorene based polymers are preferred. Most preferred are polymers, which comprise at least 5, more preferably at least 10, repeat units of the formula:

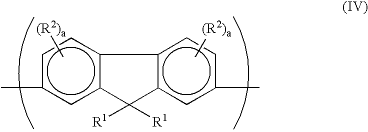

preferably having a polydispersity of less than 5, wherein R¹ is independently, in each occurrence, C₁₋₂₀ hydrocarbyl or C₁₋₂₀ hydrocarbyl containing one or more S, N, O, P or Si atoms, C₄₋₁₆ hydrocarbyl carbonyloxy, C₄₋₁₆ aryl(trialkylsiloxy) or both R¹ may form with the 9-carbon on the fluorene ring a C₅₋₂₀ ring structure or a C₄₋₂₀ ring structure containing one or more heteroatoms of S, N or O;

R² is independently, in each occurrence, C₁₋₂₀ hydrocarbyl, C₁₋₂₀ hydrocarbyloxy, C₁₋₂₀ thioether, C₁₋₂₀ hydrocarbylcarbonyloxy or cyano; and

a is independently, in each occurrence, 0 or 1. Preferably, substantially all of these repeat units are connected in the polymer chain via the 2 and 7 carbon atoms.

The polymers may be homopolymers, but more preferably, are copolymers of the above repeat unit (or mer) with one or more additional conjugated mers. Examples of these other conjugated mers include mers derived from stilbenes or 1,4-dienes, tertiary amines, N,N,N′,N′-tetraaryl-1,4-diaminobenzene, N,N,N′,N′-tetraarylbenzidine, N-substituted-carbazoles, diarylsilanes, thiophenes, furans, pyrroles, polycyclic aromatics, such as acenaphthene, phenanthrene, anthracene, fluoranthene, pyrene, perylene, rubrene, chrysene, and corene; 5-membered heterocycles containing imine linkages, such as oxazoles, isoxazoles, N-substituted-imidazoles/pyrazoles, thiazoles/isothiazoles, oxadiazoles, and N-substituted-triazoles; six-membered heterocycles containing imine linkages, such as pyridines, pyridazines, pyrimidines, pyrazines, triazines, and tetrazenes; benzo-fused heterocycles containing imine linkages, such as benzoxazoles, benzothiazole, benzimidazoles, quinolines, isoquinolines, cinnolines, quinazolines, quinoxalines, phthalazines, benzothiadiazoles, benzotriazines, phenazines, phenanthridines, and, acridines; and more complex mers, such as 1,4-tetrafluorophenylene, 1,4′-octafluorobiphenylene, 1,4-cyanophenylene, 1,4-dicyanophenylene, and

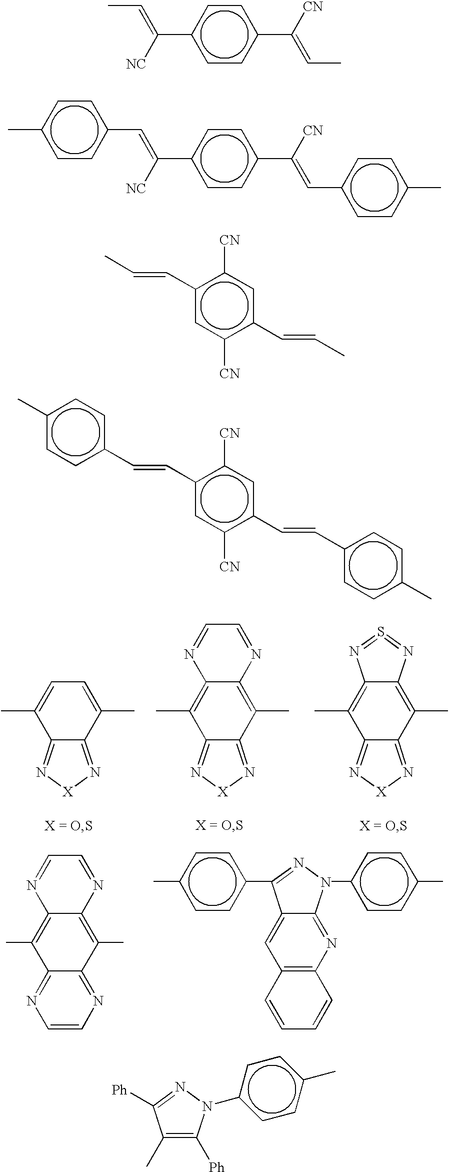

These polymeric materials may be used alone or in blends with other conjugated polymers, which, preferably, are also based on polyfluorene.

The optoelectrically active film may optionally comprise more than one layer. For instance, layers, which enhance charge injection and/or charge transport, may be used with one or both electrodes. Since holes are injected from the anode, the layer next to the anode needs to have the functionality of having holes injected into it and transporting holes. Similarly, the layer next to the cathode needs to have the functionality of transporting electrons. In many instances, the hole transporting layer or electron transporting layer may also act as the light emitting layer. In some instances, one layer can perform the combined functions of hole and electron transport, and light emission. The individual layers of the organic film may be all polymeric in nature or combinations of films of polymers and films of small molecules deposited by thermal evaporation. It is preferred that the total thickness of the organic film be less than 1000 nm. It is more preferred that the total thickness be less than 500 nm. It is most preferred that the total thickness be less than 300 nm.

The anode may be coated with a thin layer of a conducting substance to facilitate hole injection. Such substances include copper phthalocyanine, polyaniline and poly(3,4-ethylenedioxy-thiophene) (PEDOT); the last two in their conductive forms by doping with a strong organic acid, for example, poly(styrenesulfonic acid). It is preferred that the thickness of this layer be 200 nm or less; it is more preferred that the thickness be 100 nm or less. Alternatively, a more substantial separate hole-transporting layer is used, the polymeric arylamines described in U.S. Pat. No. 5,929,194, may be used. Other known hole-conducting polymers, such as polyvinylcarbazole, may also be used. The resistance of this layer to erosion by the solution of the film, which is to be applied next, is obviously critical to the successful fabrication of multi-layer solution coated devices. The thickness of this layer may be 500 nm or less, preferably 300 nm or less, most preferably 150 nm or less. Alternatively, the optional hole-transporting layer for these devices may be selected from among semi-conducting polymers, such as doped polyaniline, doped poly(3,4-ethylene-dioxythiophene), and doped polypyrrole. By “doping” is meant the blending of a semiconducting polymer (such as emeraldine base of polyaniline and poly(3,4-ethylene-dioxythiophene) with an additive, which renders the resulting polymer compositions more conductive. Preferably, the conducting polymer is derived from blending poly(3,4-ethylene-dioxythiophene) with a polymeric acid. More preferably, the polymeric acid contains sulfonic acid groups, and is most preferably poly(styrenesulfonic acid). Most preferred are polymer compositions derived from blending poly(3,4-ethylene-dioxythiophene) with at least two equivalents of poly(styrenesulfonic acid).

If an electron-transporting layer is used, it may be applied either by thermal evaporation of low molecular weight materials or by solution coating of a polymer with a solvent that would not cause significant damage to the underlying film. Examples of low molecular weight materials include the metal complexes of 8-hydroxyquinoline (as described in Burrows, et al., Applied Physics Letters, Vol. 64, pp. 2718-2720 (1994)); metallic complexes of 10-hydroxybenzo(h)quinoline (as described in Hamada, et al., Chemistry Letters, pp. 906-906 (1993)); 1,3,4-oxadiazoles (as described in Hamada, et al., Optoelectronics—Devices and Technologies, Vol. 7, pp. 83-93 (1992)); 1,3,4-triazoles (as described in Kido, et al., Chemistry Letters, pp. 47-48 (1996)); and dicarboximides of perylene (as described in Yoshida, et al., Applied Physics Letters, Vol. 69, pp. 734-736 (1996)). Polymeric electron-transporting materials are exemplified by 1,3,4-oxadiazole-containing polymers (as described in Li, et al., Journal of Chemical Society, pp. 2211-2212 (1995), and in Yang and Pei, Journal of Applied Physics, Vol. 77, pp. 4807 to 4809 (1995)); 1,3,4-triazole-containing polymers (as described in Strukelj, et al., Science, Vol. 267, pp. 1969 to 1972 (1995)); quinoxaline-containing polymers (as described in Yamamoto, et al., Japan Journal of Applied Physics, Vol. 33, pp. L250 to L253 (1994), and in O'Brien, et al., Synthetic Metals, Vol. 76, pp. 105 to 108 (1996)); and cyano-PPV (as described in Weaver, et al., Thin Solid Films, Vol. 273, pp. 39 to 47 (1996)). The thickness of this layer may be 500 nm or less, preferably 300 nm or less, most preferably 150nm or less.

The metallic cathode may be deposited either by thermal evaporation or by sputtering. The thickness of the cathode may be from 100 nm to 10,000 nm. The preferred metals are calcium, magnesium, indium, ytterbium, and aluminum. Alloys of these metals may also be used. Alloys of aluminum containing 1 to 5 percent of lithium and alloys of magnesium containing at least 80 percent of magnesium are preferred.

The EL devices of this invention emit light when subjected to an applied voltage of 50 volt or less with luminance efficiency of at least 0.1 lumens/watt, but which may be as high as 2.5 lumens/watt.

The device may be further packaged and protected from the environment by adhering a cover, such as is disclosed in WO 00/69002, to the substrate and over the active materials. An alternative protective package could include a flexible barrier coated polymer film. This barrier coated polymer film may be similar or the same as the substrate bearing the polymerized organosilicon protective barrier or may be any other suitable material.

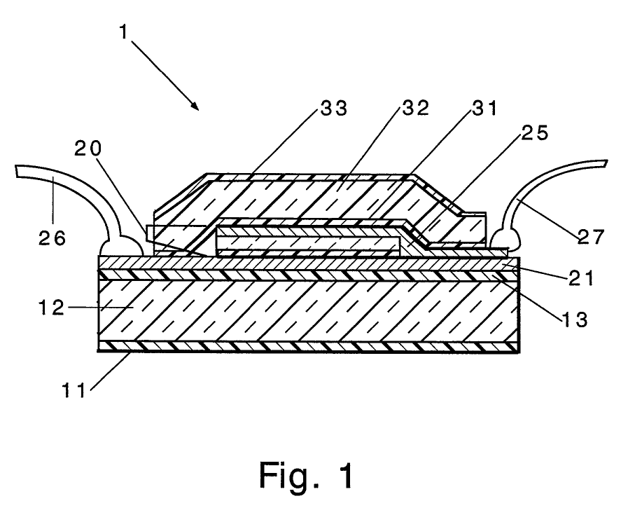

Referring now to FIG. 1, one sees a cross-section, not to scale, of a representative device 1 of this invention. This device comprises a substrate 12 having an external protective layer 11 on one side and the polymerized organosilicon protective layer 13 on the opposite side. On the polymerized organosilicon protective layer 13, the anode 21 is found. The optoelectronic or optoelectrically active film 20 is located on the anode. This film 20 comprises a hole transport layer 23 and a layer 24 of optoelectronic material. Over film 20 is found the cathode 25. Connectors 26 and 27 connect the device to a power source (for an OLED device) or to a current detector for a photodetctor. This representative device is shown with complete packaging that, in this case, comprises an internal barrier layer 31, which may be the same as or different from layer 13, a polymeric film 32, and an optional second external protective layer 33.

### EXAMPLE

The PECVD coating chamber and all substrate handling is performed in a Class 10000 clean room. Prior to deposition, all interior components of the chamber are cleaned to minimize particle contamination of the deposited films. The base substrates for the PLED devices were 300 mm×300 mm×1.0 mm polycarbonate sheets purchased from the Goodfellow Corporation. The sheets are fixtured in the plasma chamber by using binder clips and wire hangers. A single coating run is comprised of two sheets suspended vertically between the electrodes which are spaced at 25 cm. The substrates are equidistant from the electrode faces. The chamber is then evacuated to a base pressure of approximately 1 mTorr before the start of the deposition sequence. An adhesion layer is deposited using a 16.5 standard cubic centimeters per minute (sccm) flow rate of tetramethyldisiloxane (TMDSO) which is controlled by an MKS Model 1152 vapor flow controller. A 40 kHz electric field is capacitively coupled to the electrodes form an Advanced Energy Model PE II power supply. The power loaded to the plasma during the deposition of the adhesion layer is 800 W. The chamber pressure is not directly controlled in this chamber, but is rather is determined by a balance of gas flow rate into the chamber and pumping speed of unused reactants and gaseous products generated as a result of the plasma process. The process pressure for the adhesion layer is around 4-6 mTorr. The thickness of the deposited adhesion layer is approximately 100 Å, constituting a deposition time of 45 seconds. At this point, oxygen feed to the chamber is commenced at 40 sccm of oxygen using an MKS Model 1160 mass flow controller. The flow of TMDSO is then ramped from 16.5 sccm to 50 sccm over a 3 minute time span. At the completion of this ramp, the layer having the chemical composition in the range of SiO_{1.8-2.4}C_{0.3-1.0}H_{0.7-4.0} is deposited for 1 hour, which constitutes a thickness of approximately 2.5 microns. This layer is also grown with an applied power of 800 W. The process pressure for this layer is approximately 9 mTorr. When the desired thickness is attained, the vapor feed of TMDSO is reduced to 16.5 sccm, and the flow of oxygen is increased to 195 sccm over the time span of approximately 10 seconds. The applied power is increased to 1500 W, and the SiOₓ layer is grown to a thickness of approximately 300 Å in a 3 minute deposition time. When this layer is complete, the applied power is turned off and all gas feeds are ceased. The chamber is then vented to atmospheric pressure and the substrates are removed. After cleaning the electrodes and inner chamber components, the system is ready for another deposition. The anode made from indium tin oxide (ITO) is deposited over the barrier layer composition by standard plasma deposition process for ITO. Baytron-P™ polyethylene dioxythiophene from Bayer Corp. is spin coated over the ITO and is allowed to thoroughly dry. A polyfluorene based light emitting polymer is spin coated over the Baytron-P layer. The coated substrate is inserted into the vacuum metallization system, which operates at a base pressure in the 10⁻⁷ Torr (mbar) range. In this chamber, the cathode is deposited, which consists of a thin layer of calcium followed by a thicker layer of silver as a protective overcoat. The device is now operational but is further encapsulated or packaged to protect the electroactive components from damage by environmental conditions and handling. The device so made was operational in air.

What is claimed is:

1. An optoelectronic device comprising
a transparent polymeric substrate bearing on one surface thereof a transparent polymerized organosilicon protective layer,
a first electrode over the polymerized protective layer,
an optoelectrically active film comprising an electroactive material, said film having a first side, which is in contact with the transparent electrode and a second side in contact with a second electrode, wherein said first electrode is characterized in that it allows light to pass to or from the optoelectrically active film.

2. The optoelectronic device of claim 1 wherein the organosilicon protective layer has the formula SiO_{1.0-2.4}C_{0.1-4.5}H_{0.0-8.0}.

3. The optoelectronic device of claim 1 wherein the organosilicon protective layer has the formula SiO_{1.8-2.4}C_{0.3-1.0}H_{0.7-4.0}.

4. The optoelectronic device of claim 1 wherein the organosilicon protective layer is applied to the substrate by plasma enhanced chemical vapor deposition.

5. The optoelectronic device of claim 1 wherein the electroactive material is electroluminescent.

6. The optoelectronic device of claim 1 wherein the device is a photodetector.

7. The optoelectronic device of claim 1 wherein the device is a thin film transistor.

8. The optoelectronic device of claim 1 wherein the device is a photodiode.

9. The optoelectronic device of claim 1 wherein the device is a photovoltaic device.

10. The optoelectronic device of claim 1 wherein the device in an electroluminescent device.

11. The optoelectronic device of claim 1 wherein there is an adhesion promoter layer between the substrate and the protective layer.

12. The optoelectronic device of claim 11 wherein the adhesion promoter layer is applied by plasma enhanced chemical vapor deposition.

13. The optoelectronic device of claim 11 wherein the adhesion promoter layer has the formula SiO_{1.0-2.4}C_{0.1-4.5}H_{0.0-8}, with the proviso that the protective layer comprises more oxygen than does the adhesion promoter layer.

14. The optoelectronic device of claim 1 wherein a silicon oxide layer is applied between the protective layer and the first electrode.

15. The optoelectronic device of claim 11 wherein a silicon oxide layer is applied between the protective layer and the first electrode.

16. The optoelectronic device of claim 1 wherein the substrate comprises external protective coatings.

17. The optoelectronic device of claim 1 wherein the protective coating has a thickness in the range of 0.1 to 5 microns.

18. The optoelectronic device of claim 11 wherein the adhesion promoter layer has a thickness in the range of 5 to 500 nm.

19. The optoelectronic device of claim 14 wherein the adhesion promoter layer has a thickness in the range of 0.01 to 5 microns.
